(19) United States
(12) Patent Application Publication
(10) Pub. No.: US 2026/0164998 A1
(43) Pub. Date: Jun. 11, 2026

(54) DISPLAY APPARATUS AND METHOD OF MANUFACTURING THE SAME

(71) Applicant: Samsung Display Co., Ltd., Yongin-si (KR)

(72) Inventors: Eunkyung Yeon, Yongin-si (KR); Yonghoon Kwon, Yongin-si (KR); Taeoh Kim, Yongin-si (KR); Wonbeom Lee, Yongin-si (KR); Taehyeog Jung, Yongin-si (KR)

(21) Appl. No.: 19/385,925

(22) Filed: Nov. 11, 2025

(30) Foreign Application Priority Data
Dec. 5, 2024 (KR) 10-2024-0179692

(51) Int. Cl. H10K 59/80; H10K 59/12

(52) U.S. Cl. CPC H10K 59/873; H10K 59/1201

(57) ABSTRACT

Provided are a display apparatus and a method of manufacturing the same, the display apparatus including a display panel including a display area configured to display an image, an adjacent area surrounding at least a portion of the display area, and a pad area on one side of the adjacent area, a cover layer over the display panel configured to protect the display panel, an adhesive layer between the display panel and the cover layer, and a laser protection layer between the display panel and the cover layer in the adjacent area adjacent to the pad area, wherein the laser protection layer and the adhesive layer are on a same layer.

### CROSS-REFERENCE TO RELATED APPLICATION

The present application claims priority to and the benefit of Korean Patent Application No. 10-2024-0179692, filed on Dec. 5, 2024, in the Korean Intellectual Property Office, the entire disclosure of which is incorporated herein by reference.

### BACKGROUND

### 1. Field

One or more embodiments of the present disclosure relate to an apparatus and a method, and more particularly, to a display apparatus and a method of manufacturing the same.

### 2. Description of the Related Art

Recently, electronic devices have been widely used. Electronic devices may be used as mobile electronic devices and fixed electronic devices. In order to support various functions, an electronic device includes a display apparatus capable of providing a user with visual information, such as images or video.

Recently, display apparatuses have been used in a greater variety of ways. In addition, display apparatuses have become generally thinner and lighter, and an area that displays an image has generally increased while a non-display area that does not display an image has generally decreased. In addition, various materials such as glass and resin are generally used to form a cover layer for protecting a display panel.

The above information disclosed in this Background section is only for enhancement of understanding of the background of the disclosure and therefore it may contain information that does not constitute prior art.

### SUMMARY

An image emitted from a display panel may pass through a cover layer and be perceived by a user. In this regard, surface quality, for example, flatness, of the cover layer may be important for the quality of a display apparatus.

One or more embodiments include a display apparatus in which a cover layer has flatness (e.g., excellent flatness or flatness above a threshold) and a method of manufacturing the display apparatus.

Additional aspects and features will be set forth in the description that follows and, in part, may be apparent from the description, or may be learned by practicing one or more of the presented embodiments of the present disclosure.

According to one or more embodiments of the present disclosure, a display apparatus includes a display panel including a display area configured to display an image, an adjacent area surrounding at least a portion of the display area, and a pad area on one side of the adjacent area, a cover layer over the display panel configured to protect the display panel, an adhesive layer between the display panel and the cover layer, and a laser protection layer between the display panel and the cover layer in the adjacent area adjacent to the pad area, wherein the laser protection layer and the adhesive layer are on a same layer.

In an embodiment of the present disclosure, the laser protection layer may be connected to and integrally formed with an edge of the adhesive layer and may be held by the adhesive layer.

In an embodiment of the present disclosure, a thickness of the laser protection layer may be equal to a thickness of the adhesive layer.

In an embodiment of the present disclosure, in a plan view, the laser protection layer may be inside a perimeter of the cover layer.

In an embodiment of the present disclosure, in a plan view, the cover layer may include a light-blocking layer arranged along an outer perimeter thereof, wherein the laser protection layer may overlap the light-blocking layer.

In an embodiment of the present disclosure, the laser protection layer may absorb ultraviolet or infrared light.

In an embodiment of the present disclosure, the laser protection layer may include at least one of a triazine type, a benzophenone type, a benzotriazole type, an anthraquinone type, and a distyrylbiphenyl derivative.

In an embodiment of the present disclosure, the laser protection layer may include at least one of 1,1,5,5-tetrakis [4-(diethylamino)phenyl]-1,4-pentadiene-3-ylium and p-toluenesulfonate.

In an embodiment of the present disclosure, the laser protection layer may include a metal material.

In an embodiment of the present disclosure, the laser protection layer may include a base layer and a metal coating layer on the base layer.

In an embodiment of the present disclosure, the cover layer may include a film layer arranged over the display panel, and a resin layer arranged on the film layer.

According to one or more embodiments of the present disclosure, a method of manufacturing a display apparatus includes arranging a display panel including a display area displaying an image, an adjacent area surrounding at least a portion of the display area, and a pad area arranged on one side of the adjacent area, arranging an adhesive layer and a laser protection layer integrally formed with the adhesive layer on the display panel, arranging a cover layer over the adhesive layer and the laser protection layer, and cutting the cover layer and the display panel by performing laser irradiation along a perimeter of the cover layer, wherein the laser protection layer absorbs or reflects a laser beam without being cut, and substantially shields a portion of the display panel that is arranged under the laser protection layer.

In an embodiment of the present disclosure, the laser protection layer may be connected to and integrally formed with an edge of the adhesive layer and may be held by the adhesive layer.

In an embodiment of the present disclosure, a thickness of the laser protection layer may be substantially equal to a thickness of the adhesive layer.

In an embodiment of the present disclosure, in a plan view, the laser protection layer may be inside a perimeter of the cover layer.

In an embodiment of the present disclosure, in the plan view, the cover layer may include a light-blocking layer arranged along an outer perimeter thereof, wherein the laser protection layer may overlap the light-blocking layer.

In an embodiment of the present disclosure, the laser protection layer may absorb ultraviolet or infrared light.

In an embodiment of the present disclosure, the laser protection layer may include at least one of a triazine type, a benzophenone type, a benzotriazole type, an anthraquinone type, or a distyrylbiphenyl derivative.

In an embodiment of the present disclosure, the laser protection layer may include at least one of 1,1,5,5-tetrakis [4-(diethylamino)phenyl]-1,4-pentadiene-3-ylium or p-toluenesulfonate.

In an embodiment of the present disclosure, the laser protection layer may include a metal material.

According to one or more embodiments of the present disclosure, an electronic device includes a display apparatus, and a housing accommodating the display apparatus, wherein the display apparatus includes a display panel comprising a display area configured to display an image, an adjacent area surrounding at least a portion of the display area, and a pad area on one side of the adjacent area, a cover layer over the display panel configured to protect the display panel, an adhesive layer between the display panel and the cover layer, and a laser protection layer between the display panel and the cover layer in the adjacent area adjacent to the pad area, wherein the laser protection layer and the adhesive layer are on a same layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of an electronic device according to an embodiment of the present disclosure;

FIG. 2 is a schematic plan view of a display apparatus according to an embodiment of the present disclosure;

FIG. 3 is a schematic cross-sectional view of a display apparatus according to an embodiment of the present disclosure;

FIG. 4 is another schematic cross-sectional view of a display apparatus according to an embodiment of the present disclosure;

FIG. 5 is a schematic cross-sectional view of a display panel according to an embodiment and may be an enlarged cross-sectional view of a display panel of FIG. 3;

FIG. 6 is a circuit diagram schematically showing a pixel circuit applicable to a display panel according to an embodiment of the present disclosure; and

FIGS. 7 to 13 are schematic diagrams of a method of manufacturing a display apparatus, according to an embodiment of the present disclosure.

### DETAILED DESCRIPTION

The present disclosure may be embodied in various different forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Reference will now be made in more detail to one or more embodiments, examples of which are illustrated in the accompanying drawings, wherein like reference numerals refer to like elements throughout, and duplicative descriptions thereof may not be provided. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

As used herein, the term “and/or” includes any and all combinations of one or more of the associated listed items. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from a, b, and c,” “at least one from among a, b, and c,” “one from among a, b, and c”, “at least one of a to c” indicates only a, only b, only c, both a and b, both a and c, both b and c, all of a, b, and c, or variations thereof.

As the present description allows for one or more suitable changes and numerous embodiments, certain embodiments will be illustrated in the drawings and described in the written description. Aspects and features of one or more embodiments and methods of accomplishing the same will become apparent from the following detailed description of the one or more embodiments, taken in conjunction with the accompanying drawings. However, the present embodiments may have different forms and should not be construed as being limited to the descriptions set forth herein.

One or more embodiments will be described in more detail with reference to the accompanying drawings. Those elements that may each independently be the same or are in correspondence with each other are rendered the same reference numeral regardless of the drawing number, and redundant descriptions thereof are omitted.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The singular forms “a,” “an,” and “the” as used herein are intended to include the plural forms as well unless the context clearly indicates otherwise.

It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof.

It will be further understood that, when a layer, region, or element is referred to as being on another layer, region, or element, it may be directly or indirectly on the other layer, region, or element. That is, for example, intervening layers, regions, or elements may be present.

It will be further understood that, when layers, regions, or elements are referred to as being connected to each other, they may be directly connected to each other and/or may be indirectly connected to each other with intervening layers, regions, or elements therebetween. In addition, when layers, regions, or elements are referred to as being electrically connected to each other, they may be directly electrically connected to each other and/or may be indirectly electrically connected to each other with intervening layers, regions, or elements therebetween.

Sizes of elements in the drawings may be exaggerated or reduced for convenience of explanation. For example, because sizes and thicknesses of elements in the drawings are illustrated (e.g., arbitrarily illustrated) for convenience of description, the embodiments of the present disclosure are not limited thereto.

As used herein, the expression “A and/or B” refers to A, B, or A and B. Expressions such as “at least one of,” when preceding a list of elements, modify the entire list of elements and do not modify the individual elements of the list. For example, the expression “at least one of A, B, or C,” “at least one of A, B, or C,” and “at least one selected from the group consisting of A, B, and C” refers to only A, only B, only C, both A and B, both A and C, both B and C, or all of A, B, and C.

As used herein, the description that a wire “extends in a first direction or a second direction” covers not only a case where the wire extends in a straight line but also a case where the wire extends in a zigzag or curve in the first or second direction.

As used herein, the phrase “in a plan view” indicates that a portion of a target object is seen from above. The phrase “in a cross-sectional view” indicates that a portion of a target object is vertically cut and the cross-section is viewed from the side. As used herein, the description that a first element “overlaps” a second element means that the first element is on or under the second element.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

When an embodiment may be implemented differently, a certain process order may be performed differently from the described order. For example, two consecutively described processes may be performed substantially at the same time or performed in an order opposite to the described order.

The expression indicating that the two comparison targets are “substantially equal” or have a “substantial” characteristic may include a case in which a deviation considered as being at a low level in the art may be present, for example, a deviation within 5% is present.

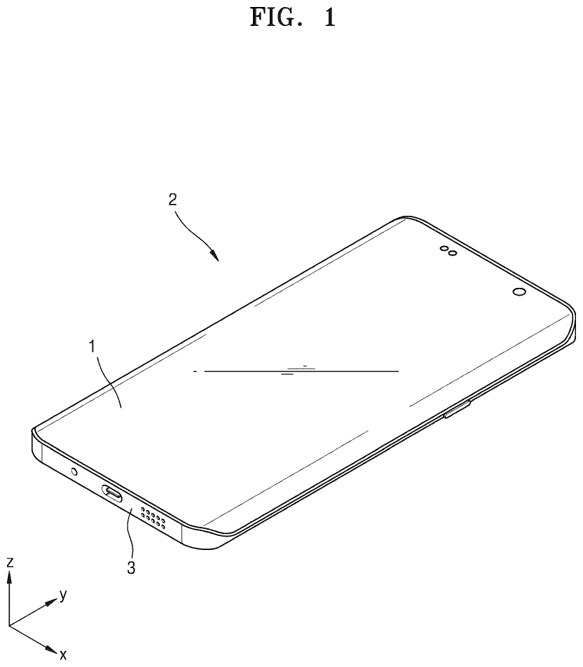

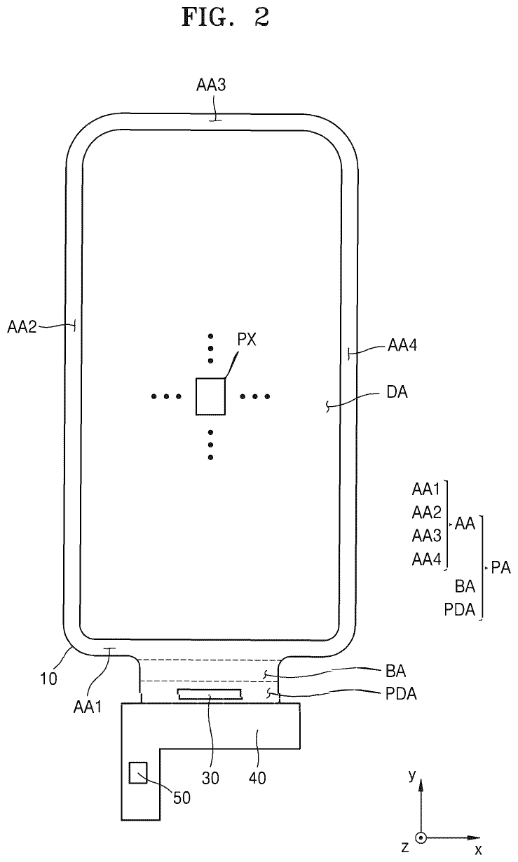

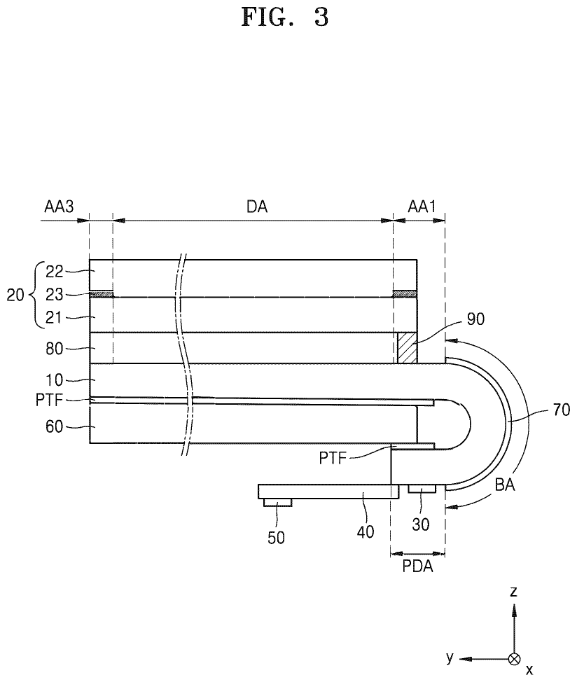

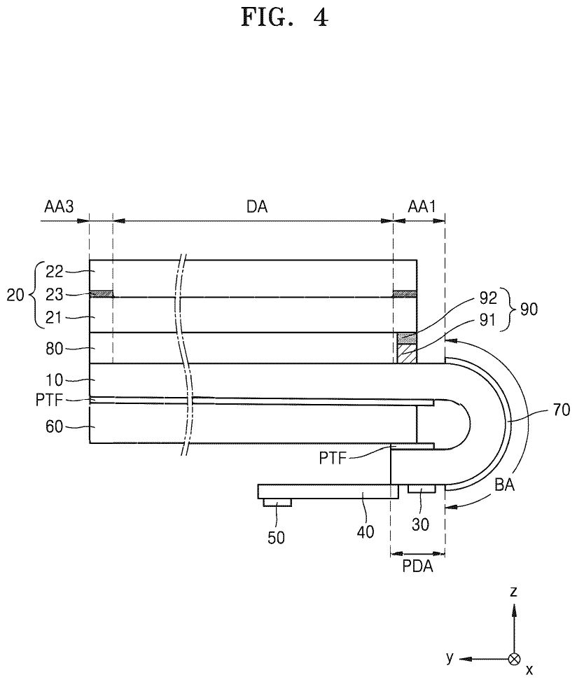

FIG. 1 is a schematic perspective view of an electronic device 2 according to an embodiment of the present disclosure. FIG. 2 is a schematic plan view of a display apparatus 1 according to an embodiment of the present disclosure. FIG. 3 is a schematic cross-sectional view of the display apparatus 1 according to an embodiment of the present disclosure. FIG. 4 is a schematic cross-sectional view of the display apparatus 1 according to another embodiment of the present disclosure.

Referring to FIGS. 1 and 2, the display apparatus 1 is an apparatus that displays a moving image or a still image and may display a screen or perform data input and output in the electronic device 2. Although FIG. 1 shows an embodiment in which the display apparatus 1 is used in a mobile phone, one or more embodiments are not limited thereto, and the display apparatus 1 may be used as a display screen for not only portable electronic devices, such as a mobile phone, a smartphone, a tablet personal computer (PC), a mobile communication terminal, an electronic notebook, an e-book, a portable multimedia player (PMP), a navigation system, and an ultra-mobile PC (UMPC), but also various electronic devices, such as a television, a notebook computer, a monitor, a billboard, and/or an Internet of things (IoT) device. In some embodiments, the display apparatus 1 may be used in electronic devices such as wearable devices, for example, a smartwatch, a watch phone, a glasses-type display, and/or a head-mounted display (HMD). In some embodiments, the display apparatus 1 may be used as a display for various electronic devices, for example, a car's instrument panel, a center information display (CID) placed on a car's center fascia or dashboard, a room mirror display replacing a car's side mirror, and/or a display placed on the back of a front seat as entertainment for a car's rear seat.

In an embodiment of the present disclosure, the display apparatus 1 may be accommodated in a housing 3 of the electronic device 2. The housing 3 may be a cover that protects internal elements, such as the display apparatus 1, and forms an exterior of the electronic device 2. In some embodiments, the display apparatus 1 may be connected to an electronic module of the electronic device 2 and be driven on the electronic device 2.

As shown in FIG. 2, the display apparatus 1 may have a substantially rectangular shape. For example, as shown in FIG. 2, the display apparatus 1 may have a rectangular planar shape as a whole with first (e.g., short) sides extending in a first direction (e.g., a direction x or a direction −x) and second (e.g., long) sides extending in a second direction (e.g., a direction y or a direction −y). In an embodiment of the present disclosure, a region where a short side extending in the first direction (e.g., the direction x or the direction −x) and a long side extending in the second direction (e.g., the direction y or the direction −y) meet each other may have a right-angled shape or may have a round shape with a certain curvature. A planar shape of the display apparatus 1 is not limited to a rectangular shape, and the display apparatus 1 may have another polygonal shape, a circular shape, an oval shape, or the like.

The display apparatus 1 may include a display area DA and a peripheral area PA. The display area DA may display an image. In this regard, pixels PX may be arranged in the display area DA. The display apparatus 1 may provide an image by using light emitted from the pixels PX. One or more (e.g., each) of the pixels PX may emit light by using a display element. In an embodiment of the present disclosure, one or more (e.g., each) of the pixels PX may emit red, green, or blue light. In an embodiment of the present disclosure, one or more (e.g., each) of the pixels PX may emit red, green, blue, or white light.

The peripheral area PA is an area where no image is provided, and may be a non-display area. The peripheral area PA may at least partially surround the display area DA. For example, the peripheral area PA may entirely surround the display area DA. A driver configured to provide an electrical signal to the pixels PX or power wiring for providing power may be arranged in the peripheral area PA. For example, a scan driver for applying a scan signal to the pixels PX may be arranged in the peripheral area PA. In some embodiments, a data driver for applying a data signal to the pixels PX may be arranged in the peripheral area PA.

FIG. 2 schematically shows a portion of the display apparatus 1 that is not yet bent, and FIG. 3 schematically shows a portion of the display apparatus 1 that has been bent, according to one or more embodiments

Referring to FIGS. 2 and 3, the display apparatus 1 may include a display panel 10, a cover layer 20, a display driver 30, a display circuit board 40, a touch sensor driver 50, a cushion layer 60, a protection film PTF, a bending protection layer 70, an adhesive layer 80, and a laser protection layer 90.

The display panel 10 may display information processed by the display apparatus 1. For example, the display panel 10 may display execution screen information regarding an application running on the display apparatus 1, or user interface (UI) or graphic user interface (GUI) information according to the execution screen information.

The display panel 10 may include a display element. For example, the display panel 10 may be an organic light-emitting display panel using an organic light-emitting diode, a micro light-emitting diode (LED) display panel using a micro LED, a quantum-dot light-emitting display panel using a quantum-dot light-emitting diode including a quantum-dot emission layer, or an inorganic light-emitting display panel using an inorganic light-emitting diode including an inorganic semiconductor. In one or more embodiments of the present disclosure, the display panel 10 is an organic light-emitting display panel using an organic light-emitting diode as a display element.

The display panel 10 may include a substrate 100 and a multi-layer arranged on the substrate 100. In an embodiment of the present disclosure, the display panel 10 may include the substrate 100, a pixel circuit layer PCL, a display element layer DEL, and an encapsulation layer TFE.

In an embodiment of the present disclosure, the display panel 10 may include the display area DA and the peripheral area PA surrounding at least a portion of the display area DA. The display area DA may display an image. In an embodiment of the present disclosure, the peripheral area PA may include an adjacent area AA surrounding the display area DA, a pad area PDA arranged on one side of the adjacent area AA, and a bending area BA arranged between the adjacent area AA and the pad area PDA.

The adjacent area AA may surround the display area DA, and for example, when the display area DA has a quadrilateral shape in a plan view, the adjacent area AA may include a first adjacent area AA1, a second adjacent area AA2, a third adjacent area AA3, and a fourth adjacent area AA4 surrounding respective edges of the display area DA.

The pad area PDA may be arranged outside the display area DA, for example, outside the first adjacent area AA1. In an embodiment of the present disclosure, the pad area PDA may be arranged farther from the display area DA than the bending area BA. In an embodiment of the present disclosure, the display driver 30 may be arranged in the pad area PDA, and the pad area PDA may be connected to the display circuit board 40.

The bending area BA may be arranged between the display area DA and the pad area PDA. In some embodiments, the bending area BA may be arranged between the first adjacent area AA1 and the pad area PDA. The bending area BA is an area where the display panel 10 is bent, and the display panel 10 may be bent in the bending area BA so that the pad area PDA may be arranged below the display area DA. In some embodiments, the area of the peripheral area PA visible to a user may be reduced.

The display driver 30 may be arranged in the pad area PDA. The display driver 30 may be configured to receive control signals and power voltages and generate and output signals and voltages for driving the display panel 10. The display driver 30 may include an integrated circuit (IC).

The display circuit board 40 may be electrically connected to the display panel 10. For example, the display circuit board 40 may be electrically connected to the pad area PDA by an anisotropic conductive film. The display circuit board 40 may be a flexible printed circuit board (FPCB) which is bendable, or a rigid printed circuit board (RPCB) which is solid and does not bend easily, or bends less than the FPCB. In some embodiments, the display circuit board 40 may be a complex printed circuit board including both a RPCB and an FPCB.

The touch sensor driver 50 may be arranged on the display circuit board 40. The touch sensor driver 50 may include an IC. The touch sensor driver 50 may be attached on the display circuit board 40. The touch sensor driver 50 may be electrically connected to sensor electrodes of a touch sensor layer of the display panel 10 through the display circuit board 40.

In some embodiments, a power supplier may be arranged on the display circuit board 40. The power supplier may be configured to supply a driving voltage for driving pixels of the display panel 10 and the display driver 30.

The protection film PTF may be patterned and be attached on a lower surface 10LS of the display panel 10. In an embodiment of the present disclosure, the protection film PTF may be attached on a portion of the display panel 10 excluding the bending area BA. In this regard, a first portion of the protection film PTF may be attached on a lower surface of the display panel 10 to correspond to the display area DA. A second portion of the protection film PTF may be attached on a lower surface of the display panel 10 to correspond to the pad area PDA.

In an embodiment of the present disclosure, the cushion layer 60 may be arranged between protection films PTF. In some embodiments, the cushion layer 60 is arranged under the display panel 10, and the display panel 10 is bent in the bending area BA, the cushion layer 60 may be arranged between a portion of the display panel 10 corresponding to the display area DA and a portion of the display panel 10 corresponding to the pad area PDA.

The cushion layer 60 may absorb an external impact to lessen or prevent destruction of the display panel 10. The cushion layer 60 may include polymer resin, such as polyurethane, polycarbonate, polypropylene, polyethylene, etc., or may include an elastic material, such as a sponge obtained by foam-molding rubber, a urethane-based material, or an acryl-based material.

Although not shown, a digitizer layer may be arranged on or under the cushion layer 60. The digitizer layer may include a body layer and/or a pattern layer and may detect a signal input from an external electronic pen or the like through the pattern layer. In some embodiments, the digitizer layer may detect the intensity, direction, etc., of a signal input from an electronic pen or the like.

The bending protection layer 70 may be placed over (e.g., cover) the bending area BA of the display panel 10. The bending protection layer 70 may be arranged on display panel 10 in the bending area BA and may be bent along the bending area BA. In an embodiment of the present disclosure, one end of the bending protection layer 70 may extend from the bending area BA to the adjacent area AA adjacent to the bending area BA and cover the display panel 10, and the other end of the bending protection layer 70 may extend from the bending area BA to the pad area PDA and cover the display panel 10. In an embodiment of the present disclosure, the bending protection layer 70 may include photocurable resin.

The bending protection layer 70 may protect the bending area BA from an external impact and may alleviate stress on the bending area BA. In some embodiments, by arranging the bending protection layer 70, a location of the neutral plane may be adjusted to reduce stress applied to the display panel 10.

The cover layer 20 may be arranged over the display panel 10. The cover layer 20 may protect the display panel 10 from an external impact or the like. In an embodiment of the present disclosure, the cover layer 20 may include a film layer 21 and a resin layer 22. The film layer 21 may be arranged over the display panel 10. The film layer 21 may be arranged on the adhesive layer 80 that allows the cover layer 20 to adhere to the display panel 10. In some embodiments, the adhesive layer 80 may be disposed or arranged between the display panel 10 and the film layer 21. In an embodiment of the present disclosure, the film layer 21 may include polyethylene terephthalate (PET). The film layer 21 may have high light transmittance and may protect the display panel 10 from an external impact or the like.

The resin layer 22 may be arranged on the film layer 21. The resin layer 22 may be applied to the film layer 21 and cured and thus may be formed. For example, the resin layer 22 may be cured by ultraviolet or infrared irradiation. The resin layer 22 may also have high light transmittance and may have the characteristic of being easily cut by a laser beam used in a laser process.

In an embodiment of the present disclosure, the cover layer 20 may include a light-blocking layer 23. The light-blocking layer 23 may be arranged between the film layer 21 and the resin layer 22. In an embodiment of the present disclosure, the light-blocking layer 23 may be arranged along an outer perimeter of the cover layer 20 in a plan view. For example, the light-blocking layer 23 may overlap the adjacent area AA in a plan view. The light-blocking layer 23 may include a light-blocking material configured to lessen or prevent layers below the light-blocking layer 23 from being externally visible.

The adhesive layer 80 may be disposed or arranged between the display panel 10 and the cover layer 20 to allow the cover layer 20 to adhere to the display panel 10. In an embodiment of the present disclosure, the adhesive layer 80 may be a pressure-sensitive adhesive (PSA).

The laser protection layer 90 may be arranged on one side of the adhesive layer 80. In an embodiment of the present disclosure, the laser protection layer 90 may be arranged on a layer on which the adhesive layer 80 is arranged. In this regard, the laser protection layer 90 and the adhesive layer 80 are on a same layer. In some embodiments, the laser protection layer 90 may be arranged between the display panel 10 and the cover layer 20. In some embodiments, the laser protection layer 90 may be connected to and integrally formed with the adhesive layer 80. For example, the laser protection layer 90 may be connected to and integrally formed with an edge of the adhesive layer 80 positioned in the first adjacent area AA1. In some embodiments, the laser protection layer 90 does not include an adhesive material and thus may be held by the adhesive layer 80. In an embodiment of the present disclosure, a thickness of the laser protection layer 90 may be equal (e.g., substantially equal) to a thickness of the adhesive layer 80. In some embodiments, the laser protection layer 90 may fill in a gap between the display panel 10 and the cover layer 20 and may hold the cover layer 20.

In an embodiment of the present disclosure, the laser protection layer 90 may overlap the adjacent area AA in a plan view. For example, the laser protection layer 90 may be arranged between the display panel 10 and the cover layer 20 in the adjacent area AA adjacent to the pad area PDA, for example, in the first adjacent area AA1.

In some embodiments, in an embodiment of the present disclosure, the laser protection layer 90 may be inside a perimeter of the cover layer 20 in a plan view. In some embodiments, the laser protection layer 90 may overlap the cover layer 20 in the first adjacent area AA1. In an embodiment of the present disclosure, the laser protection layer 90 may overlap the light-blocking layer 23 of the cover layer 20 in a plan view. In some embodiments, it will be understood that the laser protection layer 90 is arranged in the first adjacent area AA1 and thus may be apart from the bending protection layer 70 arranged in the bending area BA.

The laser protection layer 90 may absorb a laser beam used in a laser process. For example, the laser protection layer 90 may absorb ultraviolet or infrared light. The laser protection layer 90 may substantially shield, shelter, insulate, or protect the display panel 10 from the laser beam. More specifically, a laser beam may be applied from above the cover layer 20 to perform cutting in a cell size as described below. The laser protection layer 90 may absorb light during laser irradiation for cutting and thus may protect the display panel 10 below the laser protection layer 90, and more particularly, wires extending over the first adjacent area AA1, from a laser beam.

In an embodiment of the present disclosure, the laser protection layer 90 may include at least one of a triazine type, a benzophenone type, a benzotriazole type, an anthraquinone type, and a distyrylbiphenyl derivative to absorb ultraviolet rays. In some embodiments, the laser protection layer 90 may include at least one of 1,1,5,5-tetrakis [4-(diethylamino)phenyl]-1,4-pentadiene-3-ylium and p-toluenesulfonate to absorb infrared rays. In some embodiments, the laser protection layer 90 may be a resin curing layer including a plurality of light absorbers, for example, carbon black, graphite, a chromium-based material, and dye particles.

Referring to FIG. 4, in an embodiment of the present disclosure, the laser protection layer 90 may include a base layer 91 and a metal coating layer 92 arranged on the base layer 91. In some embodiments, the base layer 91 and the metal coating layer 92 may be connected to and integrally formed with the adhesive layer 80. In some embodiments, a thickness of the laser protection layer 90 including the base layer 91 and the metal coating layer 92 may be equal to a thickness of the adhesive layer 80. The base layer 91 may include resin. The metal coating layer 92 may protect layers below the laser protection layer 90 from a laser beam by reflecting light. In an embodiment of the present disclosure, the metal coating layer 92 may include at least one of aluminum, silver, copper, and gold, which have high light reflectivity (e.g., reflectivity above a set threshold value).

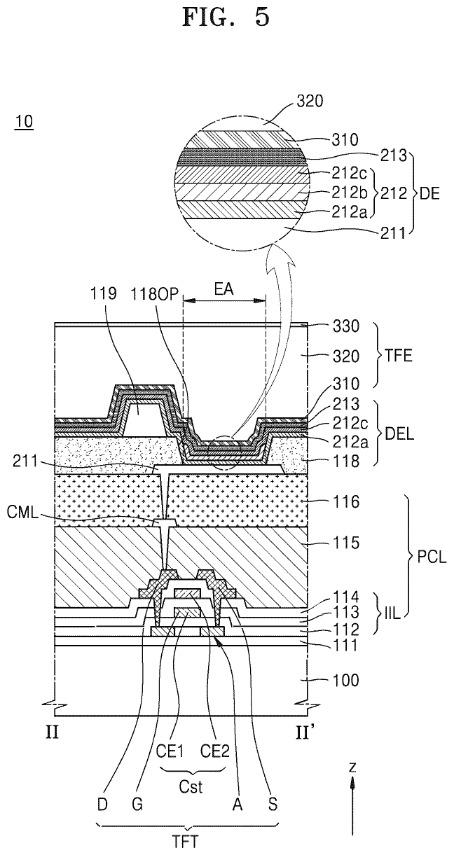

FIG. 5 is a schematic cross-sectional view of the display panel 10 according to an embodiment of the present disclosure and may be an enlarged cross-sectional view of the display panel of FIG. 3.

Referring to FIG. 5, the display apparatus 1 may include the display panel 10. In some embodiments, the display panel 10 may include the substrate 100, a buffer layer 111, the pixel circuit layer PCL, the display element layer DEL, and the encapsulation layer 300.

The substrate 100 may include glass or may include polymer resin, such as polyethersulfone, polyarylate, polyetherimide, polyethylene naphthalate, polyethylene terephthalate, polyphenylene sulfide, polyimide, polycarbonate, cellulose triacetate, or cellulose acetate propionate. In an embodiment of the present disclosure, the substrate 100 may have a multi-layer structure including a base layer and a barrier layer (not shown), the base layer including the above polymer resin. The substrate 100 including polymer resin may be flexible, rollable and/or bendable.

The buffer layer 111 may be arranged on the substrate 100. The buffer layer 111 may include an inorganic insulating material, such as silicon nitride, silicon oxynitride, and silicon oxide, and may have a single-layer or multi-layer structure including the above-described inorganic insulating material.

The pixel circuit layer PCL may be arranged on the buffer layer 111. The pixel circuit layer PCL may include a thin-film transistor TFT included in a pixel circuit, and an inorganic insulating layer IIL, a first planarization layer 115, and a second planarization layer 116 arranged below and/or over elements of the thin-film transistor TFT. The inorganic insulating layer IIL may include a first gate insulating layer 112, a second gate insulating layer 113, and an interlayer insulating layer 114.

The thin-film transistor TFT may include a semiconductor layer A, and the semiconductor layer A may include polysilicon. In some embodiments, the semiconductor layer A may include amorphous silicon, an oxide semiconductor, or an organic semiconductor. The semiconductor layer A may include a channel region, and a drain region and a source region respectively arranged on both sides of the channel region. A gate electrode G may overlap the channel region.

The gate electrode G may include a low-resistance metal material. The gate electrode G may include a conductive material including molybdenum (Mo), aluminum (Al), copper (Cu), titanium (Ti), etc., and may have a multi-layer or single-layer structure including the above-described material.

The first gate insulating layer 112 between the semiconductor layer A and the gate electrode G may include an inorganic insulating material, such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO_{X}). The zinc oxide (ZnO_{X}) may be zinc oxide (ZnO) and/or zinc peroxide (ZnO₂).

The second gate insulating layer 113 may cover the gate electrode G. Similar to the first gate insulating layer 112, the second gate insulating layer 113 may include an inorganic insulating material, such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO_{X}). The zinc oxide (ZnO_{X}) may be zinc oxide (ZnO) and/or zinc peroxide (ZnO₂).

An upper electrode CE2 of a storage capacitor Cst may be arranged on the second gate insulating layer 113. The upper electrode CE2 may overlap the gate electrode G arranged under the upper electrode CE2. In this regard, the gate electrode G and the upper electrode CE2 overlapping each other with the second gate insulating layer 113 therebetween may constitute the storage capacitor Cst of the pixel circuit. In some embodiments, the gate electrode G may serve as a lower electrode CE1 of the storage capacitor Cst. In some embodiments, the storage capacitor Cst and the thin-film transistor TFT may overlap each other. In some embodiments, the storage capacitor Cst may not overlap the thin-film transistor TFT.

The upper electrode CE2 may include aluminum (AI), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W) and/or copper (Cu), and may have a single-layer or multi-layer structure including the above-described material.

The interlayer insulating layer 114 may cover the upper electrode CE2. The interlayer insulating layer 114 may include silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO_{X}). The zinc oxide (ZnO_{X}) may be zinc oxide (ZnO) and/or zinc peroxide (ZnO₂). The interlayer insulating layer 114 may have a single-layer or multi-layer structure including the above-described inorganic insulating material.

A drain electrode D and a source electrode S may each be on the interlayer insulating layer 114. The drain electrode D and the source electrode S may each include a highly conductive material (e.g., a conductive material above a set threshold value). The drain electrode D and the source electrode S may each include a conductive material including molybdenum (Mo), aluminum (Al), copper (Cu), titanium (Ti), etc., and may have a multi-layer or single-layer structure including the above-described material. In an embodiment of the present disclosure, the drain electrode D and the source electrode S may each have a multi-layer structure of titanium (Ti)/aluminum (Al)/titanium (Ti).

The first planarization layer 115 may cover the drain electrode D and the source electrode S. The first planarization layer 115 may include an organic insulating layer. The first planarization layer 115 may include an organic insulating material, such as a general commercial polymer, such as polymethylmethacrylate (PMMA) or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof.

A connection electrode CML may be arranged on the first planarization layer 115. In this regard, the connection electrode CML may be connected to the drain electrode D or the source electrode S through a contact hole in the first planarization layer 115. The connection electrode CML may include a highly conductive material (e.g., a conductive material above a threshold value). The connection electrode CML may include a conductive material including molybdenum (Mo), aluminum (Al), copper (Cu), titanium (Ti), etc., and may have a multi-layer or single-layer structure including the above-described material. In an embodiment of the present disclosure, the connection electrode CML may have a multi-layer structure of titanium (Ti)/aluminum (Al)/titanium (Ti).

The second planarization layer 116 may cover the connection electrode CML. The second planarization layer 116 may include an organic insulating layer. The second planarization layer 116 may include an organic insulating material, such as a general commercial polymer, such as polymethylmethacrylate (PMMA) or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof.

The display element layer DEL may be arranged on the pixel circuit layer PCL. The display element layer DEL may include a display element DE. The display element DE may be an organic light-emitting diode OLED. A pixel electrode 211 of the display element DE may be electrically connected to the connection electrode CML through a contact hole in the second planarization layer 116.

The pixel electrode 211 may include conductive oxide, such as indium tin oxide (ITO), indium zinc oxide (IZO), zinc oxide (ZnO), indium oxide (In₂O₃), indium gallium oxide (IGO), or aluminum zinc oxide (AZO). In some embodiments, the pixel electrode 211 may include a reflection layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. In some embodiments, the pixel electrode 211 may further include a layer including ITO, IZO, ZnO, or In₂O₃ on/under the above-described reflection layer.

A pixel-defining layer 118 including an opening 118OP exposing a central portion of the pixel electrode 211 may be arranged on the pixel electrode 211. The pixel-defining layer 118 may include an organic insulating material and/or an inorganic insulating material. The opening 118OP may define an emission area of light emitted from the display element DE (hereinafter referred to as an emission area EA). For example, a width of the opening 118OP may correspond to a width of the emission area EA of the display element DE.

In an embodiment of the present disclosure, the pixel-defining layer 118 may include a light-blocking material that is black. The light-blocking material may include carbon black, carbon nanotubes, resin or paste including black dye, metal particles, for example, nickel, aluminum, molybdenum, and alloys thereof, metal oxide particles (e.g., chromium oxide), or metal nitride particles (e.g., chromium nitride). When the pixel-defining layer 118 includes a light-blocking material, the reflection of external light caused by metal structures arranged below the pixel-defining layer 118 may be reduced.

A spacer 119 may be arranged on the pixel-defining layer 118. The spacer 119 may be used to reduce or prevent destruction of the substrate 100 in a method of manufacturing a display apparatus. A mask sheet may be used to manufacture a display panel. In this regard, a defect may be reduced or prevented in which the mask sheet enters the opening 118OP of the pixel-defining layer 118 or comes into close contact with the pixel-defining layer 118 and thus a portion of the substrate 100 is damaged or destroyed by the mask sheet when a deposition material is deposited on the substrate 100.

The spacer 119 may include an organic insulating material, such as polyimide. In some embodiments, the spacer 119 may include an inorganic insulating material, such as silicon nitride or silicon oxide, or may include an organic insulating material and an inorganic insulating material.

In an embodiment of the present disclosure, the spacer 119 may include a different material than the pixel-defining layer 118. In some embodiments, the spacer 119 may include the same material as that of the pixel-defining layer 118, and in this case, the pixel-defining layer 118 and the spacer 119 may be formed together in a mask process using a halftone mask, etc.

An intermediate layer 212 may be arranged on the pixel-defining layer 118. The intermediate layer 212 may include an emission layer 212b arranged in the opening 118OP of the pixel-defining layer 118. The emission layer 212b may include a high-molecular weight or low-molecular weight organic material emitting light of a certain color.

A first functional layer 212a and a second functional layer 212c may be arranged under and on the emission layer 212b, respectively. The first functional layer 212a may include, for example, a hole transport layer (HTL), or an HTL and a hole injection layer (HIL). The second functional layer 212c is an element arranged on the emission layer 212b and may be optional. The second functional layer 212c may include an electron transport layer (ETL) and/or an electron injection layer (EIL). The first functional layer 212a and/or the second functional layer 212c may be common layers that cover (e.g., entirely cover) the substrate 100 as may be done by an opposite electrode 213.

The opposite electrode 213 may include a conductive material having a low work function. For example, the opposite electrode 213 may include a (semi) transparent layer including silver (Ag), magnesium (Mg), aluminum (AI), platinum (Pt), palladium (Pd), gold (Au), nickel (Ni), neodymium (Nd), iridium (Ir), chromium (Cr), lithium (Li), calcium (Ca), or an alloy thereof. In some embodiments, the opposite electrode 213 may further include a layer, such as ITO, IZO, ZnO, or In₂O₃, on a (semi) transparent layer including the above-described material.

In some embodiments, a capping layer (not shown) may be arranged on the opposite electrode 213. The capping layer may include lithium fluoride (LiF), an inorganic material, and/or an organic material.

The encapsulation layer TFE may be arranged on the opposite electrode 213. In an embodiment of the present disclosure, the encapsulation layer TFE includes at least one inorganic encapsulation layer and at least one organic encapsulation layer. FIG. 5 shows the encapsulation layer TFE including a first inorganic encapsulation layer 310, an organic encapsulation layer 320, and a second inorganic encapsulation layer 330 sequentially stacked on one another.

The first inorganic encapsulation layer 310 and the second inorganic encapsulation layer 330 may include one or more inorganic materials among aluminum oxide, titanium oxide, tantalum oxide, hafnium oxide, zinc oxide, silicon oxide, silicon nitride, and silicon oxynitride. The organic encapsulation layer 320 may include a polymer-based material. Examples of the polymer-based material may include acryl-based resin, epoxy-based resin, polyimide, and polyethylene. In an embodiment of the present disclosure, the organic encapsulation layer 320 may include acrylate.

In an embodiment of the present disclosure, a touch sensor layer (not shown) may be formed on the encapsulation layer TFE. In some embodiments, the touch sensor layer may be formed separately on a touch substrate and then coupled to the encapsulation layer TFE through an adhesive layer such as an optically clear adhesive. In an embodiment of the present disclosure, the touch sensor layer may be formed (e.g., formed directly) on the encapsulation layer TFE, and in this case, an adhesive layer may not be disposed or arranged between the touch sensor layer and the encapsulation layer TFE.

In an embodiment of the present disclosure, an optical functional layer (not shown) may be arranged on the touch sensor layer. The optical functional layer may reduce the reflectivity of light (e.g., external light) incident on the display apparatus 1 from the outside and/or may improve the color purity of light emitted from the display apparatus 1. In an embodiment of the present disclosure, the optical functional layer may include a phase retarder and a polarizer. The phase retarder may be of a film type or a liquid crystal coating type and may include a λ/2 phase retarder and/or a λ/4 phase retarder. The polarizer may also be of a film type or a liquid crystal coating type. The film type may include an elongated synthetic resin film, and the liquid crystal coating type may include liquid crystals arranged in a certain arrangement. The phase retarder and the polarizer may further include a protection film.

In some embodiments, the optical functional layer may include a black matrix and color filters. The color filters may be arranged by taking into account a color of light emitted from each of the pixels of the display apparatus 1. One or more (e.g., each) of the color filters may include a pigment or dye of a red, green, or blue color. In some embodiments, one or more (e.g., each) of the color filters may further include quantum dots (e.g., in addition to the above-described pigment or dye). In some embodiments, some of the color filters may not include the above-described pigment or dye, and may include scattered particles such as titanium oxide.

In another embodiment of the present disclosure, the optical functional layer may include a destructive interference structure. The destructive interference structure may include a first reflection layer and a second reflection layer respectively arranged on different layers. First reflected light and second reflected light respectively reflected by the first reflection layer and the second reflection layer may destructively interfere with each other, thus decreasing reflectance of external light.

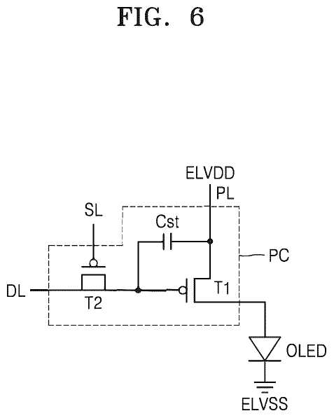

FIG. 6 is a circuit diagram schematically showing a pixel circuit PC applicable to a display panel.

Referring to FIG. 6, the pixel circuit PC may be connected to a display element, for example, an organic light-emitting diode OLED. The pixel circuit PC may include a driving thin-film transistor T1, a switching thin-film transistor T2, and the storage capacitor Cst. In some embodiments, the organic light-emitting diode OLED may emit red, green, or blue light, or may emit red, green, blue, or white light.

The switching thin-film transistor T2 may be connected to a scan line SL and a data line DL, and may be configured to transfer a data voltage or a data signal input from the data line DL to the driving thin-film transistor T1, based on a switching voltage or a scan signal input from the scan line SL. The storage capacitor Cst may be connected to the switching thin-film transistor T2 and a driving voltage line PL and may store a voltage corresponding to a difference between a voltage received from the switching thin-film transistor T2 and a first power voltage ELVDD supplied to the driving voltage line PL.

The driving thin-film transistor T1 may be connected to the driving voltage line PL and the storage capacitor Cst, and may be configured to control a driving current flowing through the organic light-emitting diode OLED from the driving voltage line PL, in response to a voltage value stored in the storage capacitor Cst. The organic light-emitting diode OLED may emit light having a certain luminance according to the driving current. An opposite electrode of the organic light-emitting diode OLED may receive a second power voltage ELVSS.

Although FIG. 6 shows the pixel circuit PC including two thin-film transistors and one storage capacitor, the pixel circuit PC may include three, four, five, or more thin-film transistors.

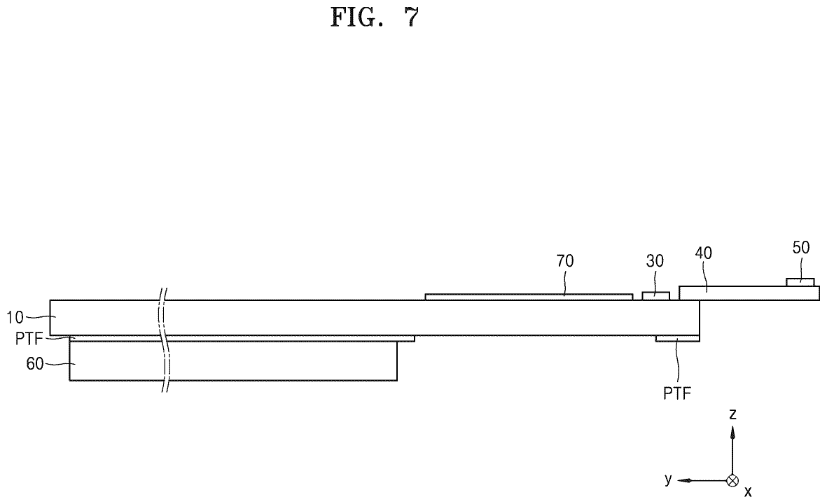

FIGS. 7 to 13 are schematic diagrams of a method of manufacturing a display apparatus, according to an embodiment of the present disclosure.

The method of manufacturing a display apparatus, according to an embodiment of the present disclosure, may be used to manufacture the display apparatus 1 described above, but one or more embodiments are not limited thereto.

Referring to FIG. 7, the display panel 10 may include the display area DA and the peripheral area PA. In some embodiments, the peripheral area PA may include the adjacent area AA at least partially surrounding the display area DA, the pad area PDA arranged on one side of the adjacent area AA, and the bending area BA arranged between the adjacent area AA and the pad area PDA.

The protection film PTF may be arranged under the display panel 10. In some embodiments, the cushion layer 60 may be arranged under the protection film PTF.

The display circuit board 40 may be connected to the display panel 10, for example, the pad area PDA.

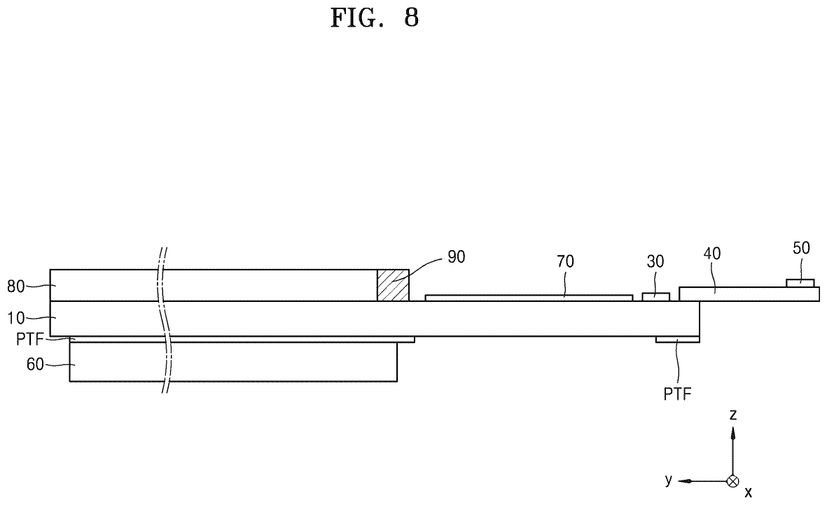

Referring to FIG. 8, the adhesive layer 80 and the laser protection layer 90 may be arranged on the display panel 10. In an embodiment of the present disclosure, the adhesive layer 80 and the laser protection layer 90 may be integrally formed with each other and arranged on the display panel 10. The adhesive layer 80 may be attached to the display panel 10, and the laser protection layer 90 may be held by the adhesive layer 80 and may be in contact with the display panel 10 without being attached thereto.

In some embodiments, the laser protection layer 90 may be connected to one edge of the adhesive layer 80, for example, an edge adjacent to the bending area BA and/or the pad area PDA. In an embodiment of the present disclosure, the laser protection layer 90 may extend in a first direction (a direction x).

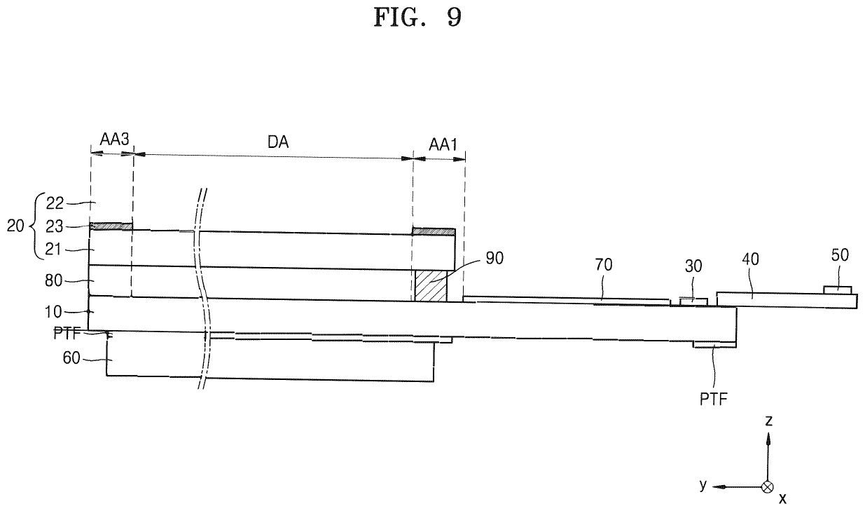

Referring to FIG. 9, the film layer 21 may be arranged on the adhesive layer 80 and the laser protection layer 90. The film layer 21 may cover (e.g., completely cover) the adhesive layer 80 and the laser protection layer 90. The film layer 21 may include, for example, polyethylene terephthalate (PET).

In some embodiments, the light-blocking layer 23 may be arranged on the film layer 21. In an embodiment of the present disclosure, the light-blocking layer 23 may be printed and arranged along edges of the film layer 21. In some embodiments, the light-blocking layer 23 may overlap the peripheral area PA, for example, the adjacent area AA. In an embodiment of the present disclosure, the light-blocking layer 23 may be provided in a closed loop.

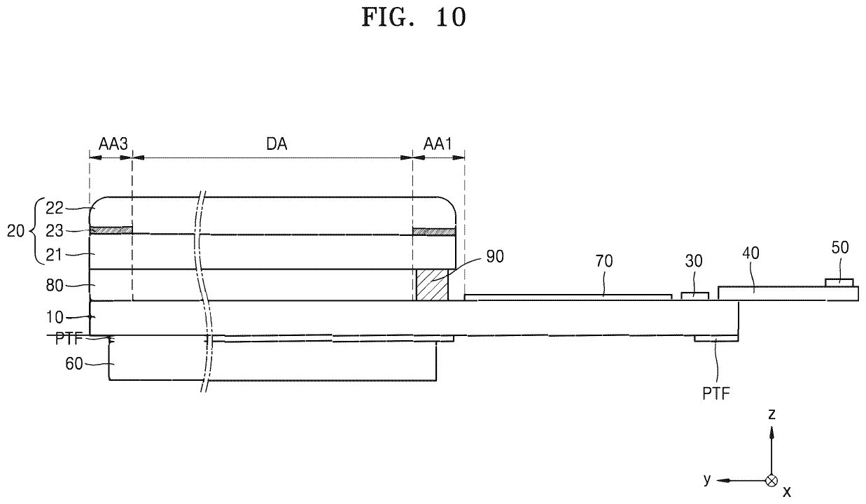

Referring to FIG. 10, resin may be applied to cover the film layer 21 and the light-blocking layer 23. After being applied, the resin may be cured to form the resin layer 22. In this regard, because the resin layer 22 is applied and cured, a bump, which is a protrusion around an edge thereof, may occur. In some embodiments, the cover layer 20 may be formed to have a size greater than the final size, and an edge portion where a bump occurs afterward may be cut. In some embodiments, the adjacent area AA of the display panel 10 corresponding thereto, for example, the second adjacent area AA2 to the fourth adjacent area AA4, may also be formed to have a size greater than the final size and may be cut together when the cover layer 20 is cut.

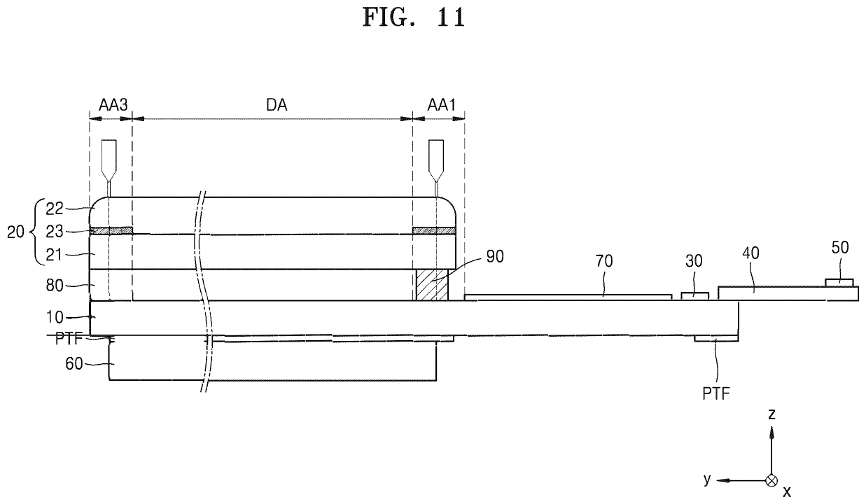

Referring to FIG. 11, the cover layer 20 may be cut offset inward along a perimeter thereof. In this regard, the cover layer 20 may be cut using a laser cutting method in which cutting is performed by laser irradiation. A laser beam may be applied from above the cover layer 20, and In some embodiments, the cover layer 20 and the display panel 10 below the cover layer 20 may be cut. In some embodiments, a portion of the display panel 10 and the cover layer 20 in the adjacent area AA may be cut. This may remove bumps around the edge of the cover layer 20, thereby improving the flatness of the cover layer 20.

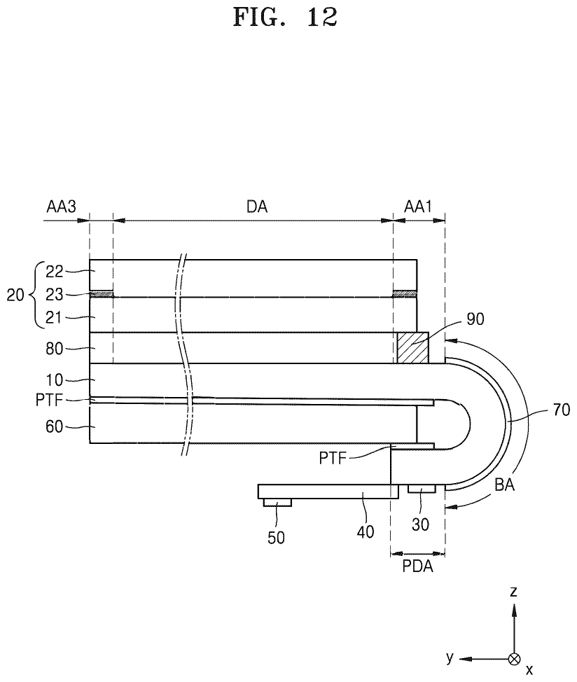

Referring to FIG. 12, as described above, the laser protection layer 90 may not be cut even when irradiated with a laser beam. In some embodiments, the display panel 10 arranged below the laser protection layer 90 may also not be cut. In some embodiments, the display panel 10 may not be cut in the first adjacent area AA1. In some embodiments, a cut surface of the cover layer 20 may overlap the laser protection layer 90 in the first adjacent area AA1. In some embodiments, in the first adjacent area AA1, a cut surface of the cover layer 20 may be at the center of a width (e.g., a length in a direction y) of the laser protection layer 90 in a plan view. In this way, the laser protection layer 90 may protect wires of the display panel 10 in the bending area BA and the first adjacent area AA1 adjacent to the pad area PDA.

Next, the display panel 10 may be bent in the bending area BA so that the pad area PDA may be arranged below the display area DA.

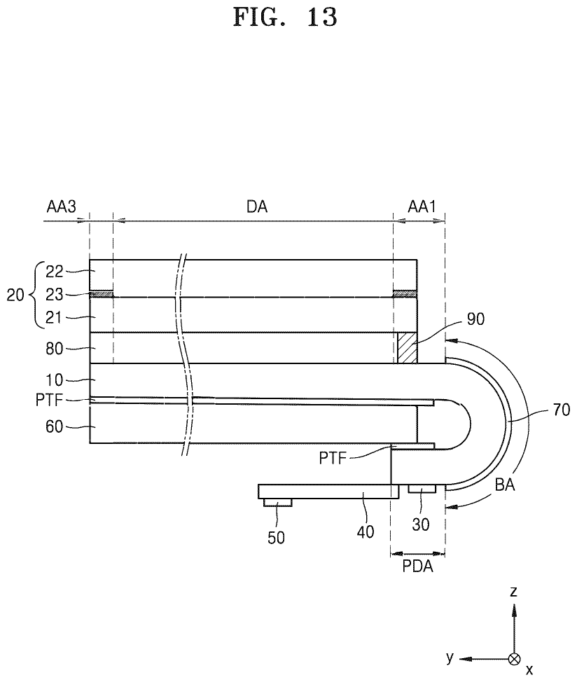

Referring to FIG. 13, the laser protection layer 90 may be cut. In an embodiment of the present disclosure, the laser protection layer 90 may be cut in line with the cut surface of the cover layer 20 in the first adjacent area AA1. In this regard, the laser protection layer 90 may be cut mechanically. For example, the laser protection layer 90 may have a scribing line formed thereon first and then be cut through a fracture process. Because the laser protection layer 90 is cut mechanically, the display panel 10 below the laser protection layer 90 may be protected, and damage to the display panel may be reduced or prevented.

According to one or more embodiments, to remove bumps in the resin layer 22, the cover layer 20 may be formed to have a size greater than the final size and then cut to be offset inward along a perimeter thereof. In this regard, the cover layer 20 may be laser cut, and in particular, the laser protection layer 90 may be arranged to prevent the adjacent area AA adjacent to the pad area PDA where many wires are arranged from being damaged by laser cutting.

According to one or more of the above embodiments, a display apparatus in which a cover layer has excellent surface quality (e.g., surface quality above a threshold value), for example, excellent flatness (e.g., flatness above a threshold value), and a method of manufacturing the display apparatus may be implemented. In some embodiments, a display apparatus in which a cover layer has excellent quality and there is no or reduced damage to a display panel and a method of manufacturing the display apparatus may be provided.

Effects of one or more embodiments are not limited thereto, and other unmentioned effects will be apparent to one of ordinary skill in the art from the following claims.

It should be understood that embodiments described herein should be considered in a descriptive sense only and not for purposes of limitation. Descriptions of features or aspects within each embodiment should typically be considered as available for other similar features or aspects in other embodiments. Although embodiments of the present disclosure have been described, it is understood that the present disclosure should not be limited to these embodiments, but one or more suitable changes and modifications can be made by one ordinary skilled in the art within the spirit and scope of the present disclosure as defined by the following claims and equivalents thereof.

What is claimed is:

1. A display apparatus comprising:
a display panel comprising a display area configured to display an image, an adjacent area surrounding at least a portion of the display area, and a pad area on one side of the adjacent area;
a cover layer over the display panel configured to protect the display panel;
an adhesive layer between the display panel and the cover layer; and
a laser protection layer between the display panel and the cover layer in the adjacent area adjacent to the pad area,
wherein the laser protection layer and the adhesive layer are on a same layer.

2. The display apparatus of claim 1, wherein the laser protection layer is connected to and integrally formed with an edge of the adhesive layer and is held by the adhesive layer.

3. The display apparatus of claim 1, wherein a thickness of the laser protection layer is substantially equal to a thickness of the adhesive layer.

4. The display apparatus of claim 1, wherein, in a plan view, the laser protection layer is inside a perimeter of the cover layer.

5. The display apparatus of claim 4, wherein, in the plan view, the cover layer comprises a light-blocking layer arranged along an outer perimeter thereof, wherein the laser protection layer overlaps the light-blocking layer.

6. The display apparatus of claim 1, wherein the laser protection layer absorbs ultraviolet or infrared light.

7. The display apparatus of claim 6, wherein the laser protection layer comprises at least one of a triazine type, a benzophenone type, a benzotriazole type, an anthraquinone type, or a distyrylbiphenyl derivative.

8. The display apparatus of claim 6, wherein the laser protection layer comprises at least one of 1,1,5,5-tetrakis [4-(diethylamino)phenyl]-1,4-pentadiene-3-ylium or p-toluenesulfonate.

9. The display apparatus of claim 1, wherein the laser protection layer comprises a metal material.

10. The display apparatus of claim 1, wherein the laser protection layer comprises a base layer and a metal coating layer on the base layer.

11. The display apparatus of claim 1, wherein the cover layer comprises:
a film layer arranged over the display panel; and
a resin layer arranged on the film layer.

12. A method of manufacturing a display apparatus, the method comprising:
arranging a display panel comprising a display area displaying an image, an adjacent area surrounding at least a portion of the display area, and a pad area arranged on one side of the adjacent area;
arranging an adhesive layer and a laser protection layer integrally formed with the adhesive layer on the display panel;
arranging a cover layer over the adhesive layer and the laser protection layer; and
cutting the cover layer and the display panel by performing laser irradiation along a perimeter of the cover layer,
wherein the laser protection layer absorbs or reflects a laser beam without being cut, and substantially shields a portion of the display panel that is arranged under the laser protection layer.

13. The method of claim 12, wherein the laser protection layer is connected to and integrally formed with an edge of the adhesive layer and is held by the adhesive layer.

14. The method of claim 12, wherein a thickness of the laser protection layer is substantially equal to a thickness of the adhesive layer.

15. The method of claim 12, wherein, in a plan view, the laser protection layer is inside a perimeter of the cover layer.

16. The method of claim 15, wherein, in the plan view, the cover layer comprises a light-blocking layer arranged along an outer perimeter thereof, wherein the laser protection layer overlaps the light-blocking layer.

17. The method of claim 12, wherein the laser protection layer absorbs ultraviolet or infrared light.

18. The method of claim 17, wherein the laser protection layer comprises at least one of a triazine type, a benzophenone type, a benzotriazole type, an anthraquinone type, a distyrylbiphenyl derivative, 1,1,5,5-tetrakis [4-(diethylamino)phenyl]-1,4-pentadiene-3-ylium, or p-toluenesulfonate.

19. The method of claim 12, wherein the laser protection layer comprises a metal material.

20. An electronic device comprising:
a display apparatus; and
a housing accommodating the display apparatus,
wherein the display apparatus comprises:
a display panel comprising a display area configured to display an image, an adjacent area surrounding at least a portion of the display area, and a pad area on one side of the adjacent area;
a cover layer over the display panel configured to protect the display panel;
an adhesive layer between the display panel and the cover layer; and
a laser protection layer between the display panel and the cover layer in the adjacent area adjacent to the pad area,
wherein the laser protection layer and the adhesive layer are on a same layer.
